(19) United States
(12) Patent Application Publication
(10) Pub. No.: US 2017/0053888 A1
(43) Pub. Date: Feb. 23, 2017

(54) METHOD OF MANUFACTURING SEMICONDUCTOR DEVICES AND CORRESPONDING SEMICONDUCTOR DEVICE

(71) Applicant: STMICROELECTRONICS S.R.L., Agrate Brianza (IT)

(72) Inventor: Federico Giovanni ZIGLIOLI, Pozzo d'adda (IT)

(21) Appl. No.: 15/134,743

(22) Filed: Apr. 21, 2016

(30) Foreign Application Priority Data
Aug. 21, 2015 (IT) 102015000045893

(51) Int. Cl. H01L 23/00

(52) U.S. Cl. CPC H01L 24/45; H01L 24/43; H01L 2224/4382; H01L 2224/45565; H01L 2224/45647; H01L 2924/35121

(57) ABSTRACT

A method is for making a semiconductor device having an IC die on a substrate with electric contact formations for the IC die and the substrate. The method may include printing ink including electrically conductive nanoparticles, onto the electric contact formations.

### RELATED APPLICATION

This application is based upon prior filed copending Italian Application No. 102015000045893 filed Aug. 21, 2015, the entire subject matter of which is incorporated herein by reference in its entirety.

### TECHNICAL FIELD

The present disclosure relates to semiconductor devices, and more particularly, to automotive integrated circuits and related methods.

### BACKGROUND

Reliability is a key factor for automotive products. This also applies to products such as semiconductor devices, where a trend exists towards increasing package robustness, for example, by way of rough surfaces on leads and any other weak areas. This may reduce the risk of delamination during Moisture Sensitivity Testing (MSL) and Temperature Cycle Testing (TC).

For instance, a layer may be formed by electroplating on the package, wires, silicon, pads and lead frame (LF). This approach may have disadvantages and difficulties related to plating processes, for example, immersing into a plating bath a strip with integrated circuit (IC) dies and wires already assembled. Also, such a process may be applicable only for products with passivated IC dies.

Roughening may be provided by way of an extra plating process, for example, with selective plating on the leads. In addition to increasing processing costs, plated roughening may involve a new wire bonding validation and/or changes in wire bonding parameters.

### SUMMARY

Generally speaking, a method is for making a semiconductor device comprising at least one IC die on a substrate with a plurality of electric contact formations for the at least one IC die and the substrate. The method may include printing ink, including electrically conductive nanoparticles, onto the plurality of electric contact formations.

### BRIEF DESCRIPTION OF THE DRAWINGS

FIG. 1 is a schematic diagram of a semiconductor device, according to the present disclosure.

FIG. 2 is an enlarged view corresponding to arrow II in FIG. 1.

FIG. 3 is another view of another embodiment, according to the present disclosure.

FIG. 4 is a flowchart of a process, according to the present disclosure.

### DETAILED DESCRIPTION

In the ensuing description one or more specific details are illustrated, aimed at providing an in-depth understanding of examples of embodiments. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments. The references used herein are provided merely for convenience and hence do not define the scope of protection or the scope of the embodiments.

The may be a desire in various areas, including the automotive sector, for semiconductor devices that may be delamination-free and exhibit high reliability. An object of one or more embodiments may be to satisfy such a need with low investments in terms of materials, time and qualification.

Some embodiments may relate to a corresponding semiconductor device, such as an IC. Some embodiments may involve, for example, aerosol or inkjet printing an ink including copper nanoparticles, for example, on leads (by taking into account that both leaded and leadless packages exist), wire bonding stitches (joints) or pad/ball bonds.

Also, printed copper nanoparticles may provide a rough morphology on the bottom surface, with a printed layer covering and closing micro-gaps possibly formed between wire bonding and a lead/pad. In one or more embodiments, roughening by printing may be “on demand” with defined geometries (e.g. by possibly creating dams or other specific shapes) on the leads and/or any other areas, with the capability of avoiding selective plating on lead frame leads.

Moreover, a roughening layer may be applied after wire bonding, so that the same wire bonding parameters of standard products may be used. Also, in one or embodiments, a wide range of materials can be applied by, for example, inkjet or aerosol jet printing. Some embodiments may offer one or more of the following advantages: flexibility in roughness morphology; rapid testing and prototyping; applicability to existing lead frames without extra costs; compatibility with a wide range of lead/wiring finishing; and improved package reliability.

FIG. 1 shows a semiconductor device 10 such as, for example, an IC. The semiconductor device 10 may include a substrate 12 having mounted thereon a semiconductor die (or chip/IC) 14 with wire bonding (generally designated 16) providing electrical connections between die pads on the semiconductor die 14 and bonding locations at the substrate 12. Electrical contact formations for the semiconductor die 14 may include, for example, one or more of wire bonding leads, wire bonding stitches, and pad/ball bonds.

A package 20 of an (e.g. electrically insulating) package molding compound (PMC) may be molded onto the substrate 12 in such a way to embed the semiconductor die or chip 14 and the associated wire bonding 16, including contact formations 18 at the substrate 12, the bonding wires, and contact formations of the wires at the die 14. The foregoing is to be held typical in the art, thus making it unnecessary to provide a more detailed description herein.

For instance, U.S. Patent Application Publication No. 2014/0284779 to Hayata et al. discloses a method of assembling semiconductor devices includes connecting a bond wire between a bond pad on a top side surface of a semiconductor die having its bottom side surface attached to a package substrate and a bonded area within a metal terminal of the package substrate, where a bond is formed along a bonding interface between the bond wire and bonded area. After the connecting, a metal paste is applied including a plurality of metal particles and a binder over the bonded area. The metal paste is sintered to densify the plurality of metal particles to form reinforcement material including within a portion of the bonding interface for providing improved wire bond performance, such as increased pull strength.

Also, various alternative techniques have been experimented in manufacturing semiconductor devices along the lines discussed in the foregoing. Ink printers are available on the market and used, for example, to create metal traces on printed circuit boards (PCBs). In addition to various dielectrics, adhesives, semiconductors and other materials, ink printers are available for printing metal inks including, for example, gold, platinum, silver, nickel, copper, aluminum as well as non-metallic conductors such as, for example, single wall carbon nanotubes, and multi wall carbon nanotubes.

Jani Miettinen, et al.: “Inkjet printed System-in-Package design and manufacturing”, Microelectronics Journal 39 (2008) 1740-1750 disclose that additive manufacturing technology using inkjet offers several improvements to electronics manufacturing compared to current non-additive masking technologies. Additive inkjet manufacturing processes are indicated as flexible, allowing fast prototyping, easy design changes and personalization of products, while also offering new possibilities to electronics integration, by enabling direct writing on various surfaces, and component interconnection without a specific substrate. Jang, Seonhee, et al, in: “Inkjet-printed gold nanoparticulate patterns for surface finish in electronic package”, Applied Physics A: Materials Science & Processing; November 2011, Vol. 105 Issue 3, p. 685, discloses gold (Au) pads for surface finish in electronic packages developed by inkjet printing suing an Au ink including Au nanoparticles (NPs) coated with capping molecules of dodecylamine (CHNH).

Aerosol jet systems were reliably used in producing ultra-fine feature circuitry well beyond the capabilities of thick-film and inkjet processes. Most materials can be written with a resolution of down to 20 μm total length of each interconnect is approximately 1.5 mm long with a throughput for a single nozzle of up to 5,000 interconnects per hour.

Aerosol jet print heads are highly scalable, and may support 2, 3, 5, or more nozzles at a time, pitch dependent, enabling throughputs as high as 25,000 or more interconnects per hour. Aerosol jet and inkjet printing may exhibit certain differences, for example, in terms of: print resolution; viscosity of ink (suspensions); and the distance from the print head to the substrate.

Aerosol printing may permit achievement of a higher print resolution, namely, almost 2-4 times higher than inkjet. For instance, resolution printing with aerosol jet may be 10 microns (10×10⁻⁶ meter), several studies reported print resolution of about 5 microns (5×10⁻⁶ meter), while using typical ink jet printing a minimum resolution of 20-25 microns (20-25×10⁻⁶ meter) may be achieved. Also, aerosol jet printing may have less strict requirements as regards ink viscosity (suspension), and therefore a wider choice of materials (including ceramics, metals, etc.) can be printed by aerosol jet printing. A range of viscosity of ink (suspension) for aerosol jet printing may be from 0.5 to 2000 cP, while ink jet ink may have a low viscosity less than 20 cP.

Additionally, aerosol jet may offer a greater opportunity to vary the distance between the print head to the substrate. Therefore, it is possible to print on non-flat (non-smooth) substrates. Aerosol jet makes it possible to create 3D-contacts which may be difficult to produce by inkjet printing. For example, a distance between the print head to the substrate in aerosol jet may be 1-5 mm, while ink jet distance may be fixed and equal, for example, to 1 mm.

Aerosol printing is a less mature technology compared to inkjet printing, which is a more mature and developed technology, offering more opportunities to apply inkjet printing to various structures. Also, at least at present, inkjet printing may be cheaper than aerosol printing, with industrial aerosol jet printers having a significantly higher cost than industrial inkjet printers.

Some embodiments may provide a method of manufacturing semiconductor devices (e.g. ICs) including one or more semiconductor IC dies or chips 14 on a substrate 12 with electrical contact formations of the wire bonding 16 for the or each semiconductor die or chip at the substrate 12. Some embodiments may provide for printing (e.g. inkjet or aerosol jet printing) ink including electrically conductive nanoparticles onto any of: contact formations 18 at the substrate 12; bonding wires 16; and contact formations of the wires 16 at the die 14, in order to form thereon a corresponding printed layer 22.

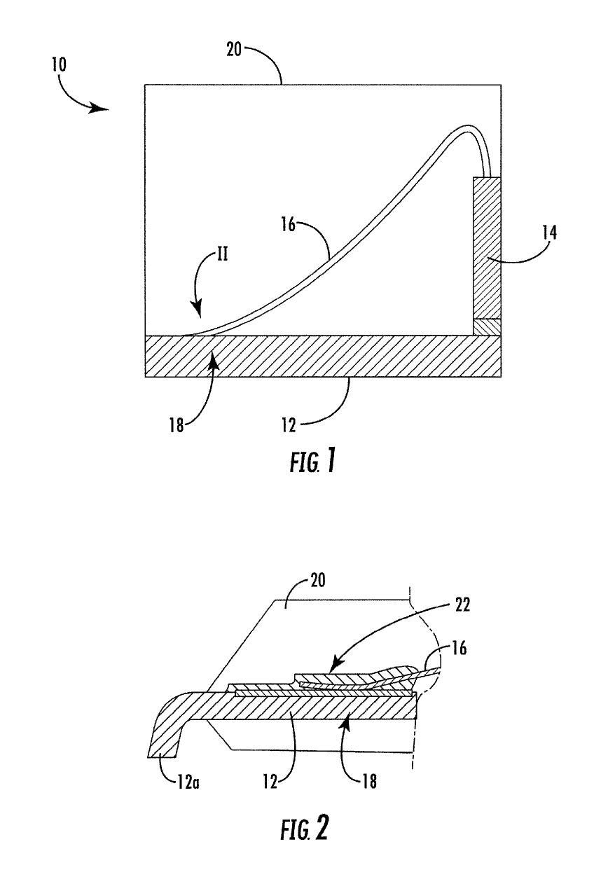

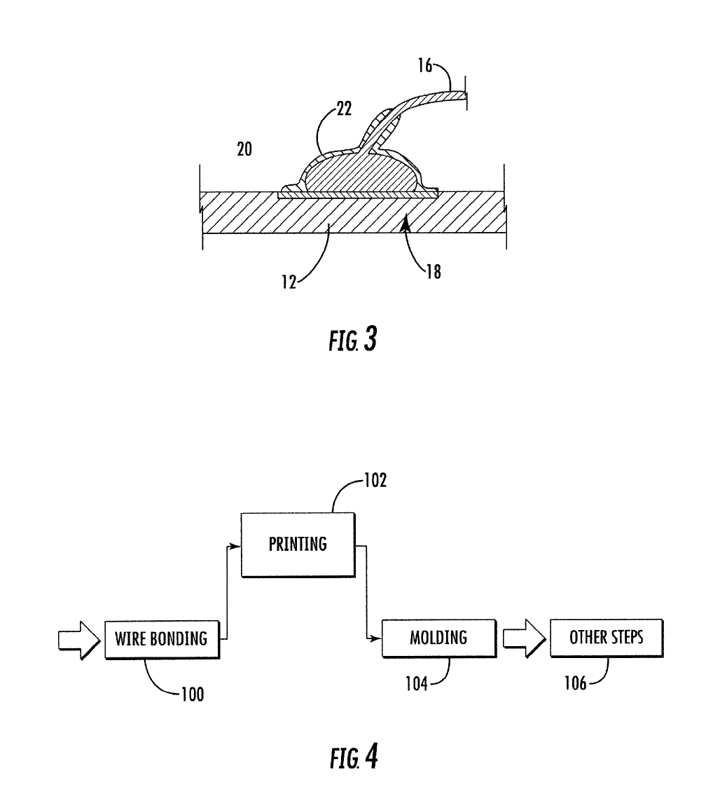

As used herein, the contact formations being referred to as located “at” the substrate 12 and/or “at” the die 14 are intended to indicate that such contact formations may be located on the substrate 12/die 14 and/or in the vicinity thereof. In some embodiments, as exemplified in FIGS. 2 and 3, such a layer 22 may be printed (only) on the contact formations 18 at the substrate 12. In one or more embodiments, printing such a layer 22 (also or exclusively) on the bonding wires 16 may be either continuous or discontinuous over the wire length, for example, only at the ends. Optionally, printing such a layer 22 (also or exclusively) on the contact formations of the wires 16 at the die 14 may take place essentially as exemplified herein in connection with the contact formations 18 at the substrate 12.

Some embodiments may provide for printing (e.g. inkjet or aerosol jet printing) ink including metal (e.g. copper) nanoparticles on leads (leaded and leadless packages), wire bonding stitches or pad/ball bonds at the locations. Optionally, such printed nanoparticles (e.g. inkjet or aerosol printed copper nanoparticles) may provide a rough morphology on the bottom surface. Also, in one or more embodiments, a resulting printed layer 22 may cover (that is fill-in) micro gaps possibly existing between wire bonding and a lead/pad.

FIGS. 2 and 3 substantially correspond to views according to arrow II in FIG. 1 enlarged to show the printed layer 22. In FIGS. 2 and 3 the same reference numerals already introduced in FIG. 1 are otherwise used to denote parts and components identical or similar to those already discussed previously: a corresponding detailed description will not be repeated here for the sake of brevity. FIG. 2 is exemplary of embodiments where, for example, the substrate 12 may include pin extensions 12a while the package 20 may be thinner than the one exemplified in FIG. 1.

These non-mandatory features (which may be applied to any other of the embodiments exemplified herein) are presented with the main purpose of showing that one or more embodiments are generally applicable to a wide variety of semiconductor devices including at least one semiconductor die or chip 14 on a substrate 12 with electrical contact formations 18 for the semiconductor die 14. Optionally, the roughening characteristics of the layer 22 may be defined, for example, by particle size, ink viscosity, solid loading, wettability, and dispersion stability, printing process and sintering temperature.

Some embodiments may provide for printing—onto the contact formations 18 at the substrate 12 and/or the bonding wires 16 and/or the contact formations of the wires 16 at the die 14—a layer 22 of ink including electrically conductive nanoparticles, such a layer having a thickness of 0.25 to 1 micrometers (0.25×10⁻⁶ to 1×10⁻⁶ meter). In one or more embodiments, the nanoparticles may have a size of 30 to 150 nanometers (30×10⁻⁹ to 150×10⁻⁹ meter).

Also, the nanoparticles may have a size of 40 to 50 nanometers (40×10⁻⁹ to 50×10⁻⁹ meter). Optionally, a treatment such as heat treatment, ultraviolet (UV) curing or (e.g. laser) sintering may be applied to the ink layer 22 including electrically conductive nanoparticles printed onto the contact formations. In one or more embodiments, heat treatment may be at a temperature up to 250 to 300° C., for example, with a process temperature not exceeding 300° C., for example, by oven thermal annealing. Optionally, sintering may be oven sintering or (e.g. pulsed) laser sintering. Some embodiments may thus permit to obtain rough leads without, for example, specific lead frame (LF) plating.

In one or more embodiments, a roughening layer 22 may be printed, for example, onto a lead and an associated wire 16 (stitch/ball) as schematically represented in FIG. 3. Optionally, a rough layer of, for example, sintered copper/metal/alloy may be provided on different substrates (copper, silver, gold) and partially on the wire 16 (stitch and ball). In one or more embodiments: wire bonding can be performed on a standard lead finishing; copper roughening SA (Surf Area/Area) can be handled by process/material properties; a roughening pattern can be “drawn” on the substrate in compliance, for example, with application requirements; and metal printing can be include copper or other metals or alloys.

FIG. 4 is a schematic representation of steps in one or more embodiments where a semiconductor device (e.g. IC) assembly flow may be standard until completing wire bonding 100. Thereafter, in one or more embodiments, wire-bonded (WB) units may proceed to a printing step/station 102 where, for example, copper ink is printed (e.g. inkjet or aerosol jet printed) onto, for example, the bonded leads and pads (e.g. the connection formations 18). Optionally, after printing, and possible heat treatment, UV curing, sintering (oven/laser), process flow may proceed as in standard IC manufacturing processes.

For instance, in one or more embodiments an, for example, electrically insulating molding compound—PMC 20 may be molded at 104 onto the semiconductor die/IC dies 14 and the substrate 12 with a layer 22 including electrically conductive nanoparticles printed onto the electrical contact formations at the substrate 12 and/or at the die 14 and/or the wires 16. In one or more embodiments, other conventional steps such as baking, plating, testing & finishing may then follow as schematically indicated at 106. Optionally, roughness as provided by the printed layer 22 was shown to provide improved compound adhesion on leads/wire, resulting, for example, in improved reliability and improved resistance to delamination.

Without prejudice to the underlying principles, the details and embodiments may vary, even significantly, with respect to what has been described by way of example only without departing from the extent of protection. The extent of protection is defined by the annexed claims.

1-10. (canceled)

11. A method of making a semiconductor device comprising at least one integrated circuit (IC) die on a substrate with a plurality of electric contact formations for the at least one IC die and the substrate, the method comprising:
printing ink including electrically conductive nanoparticles onto the plurality of electric contact formations.

12. The method of claim 11 wherein the plurality of electric contact formations comprises contact formations adjacent the substrate, a plurality of bond wires, and contact formations adjacent the at least one IC die.

13. The method of claim 11 wherein the electrically conductive nanoparticles comprise metal nanoparticles.

14. The method of claim 11 wherein the electrically conductive nanoparticles comprise copper nanoparticles.

15. The method of claim 11 wherein the electrically conductive nanoparticles have a size in a range of 30-150 nanometers.

16. The method of claim 11 further comprising printing onto the plurality of electric contact formations a layer of the ink, the layer having a thickness between 0.25-1 micrometers.

17. The method of claim 11 further comprising applying to the ink at least one of a heat treatment, an ultraviolet curing, an oven sintering, and a laser sintering,

18. The method of claim 11 further comprising heating the ink to a temperature between 250-300° C.

19. The method of claim 11 wherein the plurality of electric contact formations comprises a bind wire lead, a wire bonding joint, and a pad/ball bond.

20. The method of claim 11 further comprising forming molding material onto the at least one IC die and the substrate with the ink.

21. The method of claim 11 further comprising printing the ink by at least one of inkjet printing and aerosol jet printing.

22. A method of making a semiconductor device comprising at least one integrated circuit (IC) die on a substrate with a plurality of electric contact formations for the at least one IC die and the substrate, the method comprising:
printing ink including metal nanoparticles onto the plurality of electric contact formations; and
heating the printed ink to a threshold temperature.

23. The method of claim 22 wherein the plurality of electric contact formations comprises contact formations adjacent the substrate, a plurality of bond wires, and contact formations adjacent the at least one IC die.

24. The method of claim 22 wherein the metal nanoparticles comprise copper nanoparticles.

25. The method of claim 22 wherein the metal nanoparticles have a size in a range of 30-150 nanometers.

26. The method of claim 22 further comprising printing onto the plurality of electric contact formations a layer of the ink, the layer having a thickness between 0.25-1 micrometers.

27. The method of claim 22 further comprising applying to the ink at least one of a heat treatment, an ultraviolet curing, an oven sintering, and a laser sintering,

28. A semiconductor device comprising:
a substrate;
at least one integrated circuit (IC) die adjacent said substrate;
a plurality of electric contact formations associated with said at least one IC die and said substrate; and
a layer of ink on said plurality of electric contact formations and including metal nanoparticles.

29. The semiconductor device of claim 28 wherein said plurality of electric contact formations comprises contact formations adjacent said substrate, a plurality of bond wires between said substrate and said at least one IC die, and contact formations adjacent said at least one IC die.

30. The semiconductor device of claim 28 wherein the electrically conductive nanoparticles comprise metal nanoparticles.

31. The semiconductor device of claim 28 wherein the electrically conductive nanoparticles have a size in a range of 30-150 nanometers.

32. The semiconductor device of claim 28 further comprising molding material over said at least one IC die, said ink, and said substrate.
